(19) United States
(12) Patent Application Publication
(10) Pub. No.: US 2025/0357168 A1
(43) Pub. Date: Nov. 20, 2025

(54) APPARATUS OF TRANSFERRING AND OPERATING METHOD THEREOF

(71) Applicant: SEMES CO., LTD., Cheonan-si (KR)

(72) Inventors: Jong Ho KIM, Hwaseong-si (KR); Ji Yun PARK, Cheonan-si (KR); Doo Hee LEE, Daegu (KR); In Sung CHOI, Hwaseong-si (KR)

(73) Assignee: SEMES CO., LTD., Cheonan-si (KR)

(21) Appl. No.: 19/209,349

(22) Filed: May 15, 2025

(30) Foreign Application Priority Data
May 16, 2024 (KR) 10-2024-0063594

(51) Int. Cl. H01L 21/677; H01L 21/67

(52) U.S. Cl. CPC H01L 21/67724; H01L 21/67259; H01L 21/67715; H01L 21/67733

(57) ABSTRACT

An apparatus for transferring according to an embodiment of the present disclosure includes: a transport vehicle transporting a container with an article therein, wherein the transport vehicle may include: a driving unit including a driving wheel and an angle sensor sensing a driving angle sensing value; a trolley sensor unit including a first trolley sensor provided at a center on a front of the transport vehicle and sensing objects ahead of the transport vehicle; and a control unit controlling at least one of the driving unit and the trolley sensor unit on the basis of a driving angle sensing value of the angle sensor and a first trolley sensing value of the first trolley sensor.

### CROSS-REFERENCE TO RELATED APPLICATIONS

This application claims priority to and the benefit of Korean Patent Application No. 10-2024-0063594 filed in the Korean Intellectual Property Office on May 16, 2024, the entire contents of which are incorporated herein by reference.

### TECHNICAL FIELD

The present disclosure relates to an apparatus for transferring and an operating method of the apparatus.

### BACKGROUND ART

In general, in order to manufacture a semiconductor device, various types of processes such as deposition, photolithography, and etching are performed, and the apparatuses that perform these processes, respectively, are arranged in a semiconductor manufacturing line. Articles such as substrates, which are objects to be processed in semiconductor device manufacturing processes (for example, wafers and glass), may be provided to each semiconductor processing device while housed in containers such as FOUPs and PODs. Further, the articles that have undergone processing are collected into containers from each semiconductor processing device, and the collected containers may be transported to the outside.

Containers are transported by transport vehicles such as an Overhead Hoist Transport Apparatus (OHT). Transport vehicles transport containers containing articles to a load port of one of the semiconductor processing devices. Further, transport vehicles can pick up containers with processed articles from a load port and transport them to the outside or transfer them to another one of the semiconductor processing devices. Transport vehicles transport containers with the articles inside while traveling along rails installed on the ceiling of the semiconductor manufacturing line. The rails may include straight sections and curved sections. A plurality of transport vehicles travel along straight sections and curved sections, and when another transport vehicle is stationary ahead of a transport vehicle, the transport vehicle can detect the other transport vehicle. When another transport vehicle is detected, the transport vehicle can stop, which can prevent a collision with the other transport vehicle. However, when a transport vehicle travels along straight sections, there is no issue in detecting another transport vehicle ahead, but when a transport vehicle enters curved sections, it may fail to detect another transport vehicle ahead due to sensor sensitivity and sensor performance variation, which may result in a collision with the other transport vehicle.

### SUMMARY OF THE INVENTION

An objective of the present disclosure is to provide an apparatus for transferring that can efficiently transport container with article therein, and an operating method for the apparatus.

An objective of the present disclosure is to provide an apparatus for transferring that can prevent collisions between transport vehicles in curved sections, and an operating method for the apparatus.

The objectives of the present disclosure are not limited thereto and other objectives not stated herein may be clearly understood by those skilled in the art from the following description.

An exemplary embodiment of the present invention provides an apparatus for transferring that comprises a transport vehicle transporting a container with an article therein, wherein the transport vehicle may include, a driving unit including a driving wheel and an angle sensor sensing a driving angle sensing value; a trolley sensor unit including a first trolley sensor provided at a center on a front of the transport vehicle and sensing objects ahead of the transport vehicle; and a control unit controlling at least one of the driving unit and the trolley sensor unit on the basis of a driving angle sensing value of the angle sensor and a first trolley sensing value of the first trolley sensor.

According to the exemplary embodiment of the present invention, the trolley sensor unit may include an actuating unit changing a sensing angle of the first trolley sensor.

According to the exemplary embodiment of the present invention, the actuating unit may include: a power transmission member connected to the first trolley sensor; and a power supply member supplying power to the power transmission member.

According to the exemplary embodiment of the present invention, the control unit may controls the actuating unit on the basis of the driving angle sensing value such that the driving angle and the sensing angle are matched.

According to the exemplary embodiment of the present invention, the control unit determines whether the transport vehicle has entered a turning section on the basis of the driving angle sensing value when the transport vehicle is traveling in a straight section at a first speed; controls the driving unit to decrease a driving speed of the transport vehicle from the first speed to a second speed when the transport vehicle has entered the turning section; and may determines whether there is another transport vehicle preceding the transport vehicle on the basis of the first trolley sensing value.

According to the exemplary embodiment of the present invention, when there is the other transport vehicle, the control unit may controls the driving unit to stop the transport vehicle.

According to the exemplary embodiment of the present invention, the control unit repeatedly may determines whether there is the other transport vehicle on the basis of the first trolley sensing value.

According to the exemplary embodiment of the present invention, the control unit determines whether the transport vehicle has entered the straight section on the basis of the driving angle sensing value when there is no other transport vehicle as the result of determination; and may controls the driving unit to increase the driving speed of the transport vehicle from the second speed to the first speed when the transport vehicle has entered the straight section.

According to the exemplary embodiment of the present invention, the trolley sensor unit further may include, a second trolley sensor provided at one side of the front of the transport vehicle and sensing objects ahead of the transport vehicle; and a third trolley sensor provided at another side of the front of the transport vehicle and sensing objects ahead of the transport vehicle.

According to the exemplary embodiment of the present invention, the control unit may controls the driving unit and the trolley sensor unit on the basis of at least one of the driving angle sensing value, the first trolley sensing value, a second trolley sensing value of the second trolley sensor, and a third sensing value of the third trolley sensor.

According to the exemplary embodiment of the present invention, the apparatus may further include a rail installed on a ceiling of a manufacturing line where semiconductor processing devices are continuously arranged; and a port configured such that the container can be seated thereon.

An exemplary embodiment of the present invention provides a method of operating an apparatus for transferring, the method comprising: determining whether a transport vehicle has entered a turning section on the basis of a driving angle sensing value sensed through an angle sensor; decelerating a driving speed of the transport vehicle when the transport vehicle has entered the turning section; determining whether there is another transport vehicle preceding the transport vehicle on the basis of a trolley sensing value sensed through a trolley sensor; and stopping or continuing to travel at a decelerated speed on the basis of whether there is the other transport vehicle, wherein a sensing value of the trolley sensor may be changed on the basis of the driving angle sensing value.

According to the exemplary embodiment of the present invention, the stopping or continuing to travel at a decelerated speed on the basis of whether there is the other transport vehicle may include stopping when there is the other transport vehicle.

According to the exemplary embodiment of the present invention, the stopping or continuing to travel at a decelerated speed on the basis of whether there is the other transport vehicle may include determining again whether there is the other transport vehicle when there is no other transport vehicle.

According to the exemplary embodiment of the present invention, the determining of whether there is the other transport vehicle when there is no other vehicle may be repeatedly performed on the basis of a preset number of times.

According to the exemplary embodiment of the present invention, the stopping or continuing to travel at a decelerated speed on the basis of whether there is the other transport vehicle may include: determining whether the transport vehicle has entered a straight section on the basis of the driving angle sensing value sensed by the angle sensor when there is no other transport vehicle; and increasing the driving speed of the transport vehicle when the transport vehicle has entered the straight section.

An exemplary embodiment of the present invention provides an apparatus for transferring, comprising: a rail provided along a ceiling; a port configured such that a container can be seated thereon; and a transport vehicle traveling along the rail and transporting the container to the port, wherein the transport vehicle includes: a driving unit having a driving wheel; an angle sensor unit including an angle sensor sensing a driving angle sensing value; a trolley sensor unit including a first trolley sensor provided at a center on a front of the transport vehicle and sensing objects ahead of the transport vehicle; and a control unit controlling at least one of the driving unit and the trolley sensor unit on the basis of a driving angle sensing value of the angle sensor and a first trolley sensing value of the first trolley sensor, wherein the trolley sensor unit includes an actuating unit changing a sensing angle of the first trolley sensor, wherein the actuating unit includes: a power transmission member connected to the first trolley sensor; and a power supply member supplying power to the power transmission member, wherein the control unit controls the actuating unit on the basis of the driving angle sensing value such that the driving angle and the sensing angle are matched; determines whether the transport vehicle has entered a turning section on the basis of the driving angle sensing value when the transport vehicle is traveling in a straight section at a first speed; controls the driving unit to decrease a driving speed of the transport vehicle from the first speed to a second speed when the transport vehicle has entered the turning section; and may determines whether there is another transport vehicle preceding the transport vehicle on the basis of the first trolley sensing value.

According to the exemplary embodiment of the present invention, when there is the other transport vehicle, the control unit may controls the driving unit to stop the transport vehicle.

According to the exemplary embodiment of the present invention, the control unit repeatedly determines whether there is the other transport vehicle on the basis of the first trolley sensing value; determines whether the transport vehicle has entered the straight section on the basis of the driving angle sensing value when there is no other transport vehicle as the result of determination; and may controls the driving unit to increase the driving speed of the transport vehicle from the second speed to the first speed when the transport vehicle has entered the straight section.

According to the exemplary embodiment of the present invention, the trolley sensor unit further includes: a second trolley sensor provided at one side of the front of the transport vehicle and sensing objects ahead of the transport vehicle; and a third trolley sensor provided at another side of the front of the transport vehicle and sensing objects ahead of the transport vehicle, and the control unit may controls the driving unit and the trolley sensor unit on the basis of at least one of the driving angle sensing value, the first trolley sensing value, a second trolley sensing value of the second trolley sensor, and a third sensing value of the third trolley sensor.

According to the exemplary embodiment of the present invention, it is possible to efficiently transport containers with articles therein.

According to the exemplary embodiment of the present invention, it is possible to prevent collisions between transport vehicles in turning sections and reduce the processing costs and processing time required for transporting articles.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a plan view schematically showing an apparatus for transferring according to an embodiment of the present disclosure, viewed from above.

FIG. 2 is a plan view schematically showing a transport vehicle according to an embodiment of the present disclosure, viewed from the front.

FIG. 3 is a plan view schematically showing the transport vehicle according to an embodiment of the present disclosure, viewed from the side.

FIG. 4 is a plan view schematically showing a transport vehicle according to an embodiment of the present disclosure, viewed from above.

FIG. 5 is a conceptual view schematically showing a trolley sensor unit according to an embodiment of the present disclosure.

FIG. 6 is a flowchart showing a method of operating a transport vehicle according to an embodiment of the present disclosure.

FIG. 7 is a conceptual view illustrating a transport method according to an embodiment of the present disclosure.

FIG. 8 is a plan view schematically showing a transport vehicle according to another embodiment of the present disclosure, viewed from the front.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

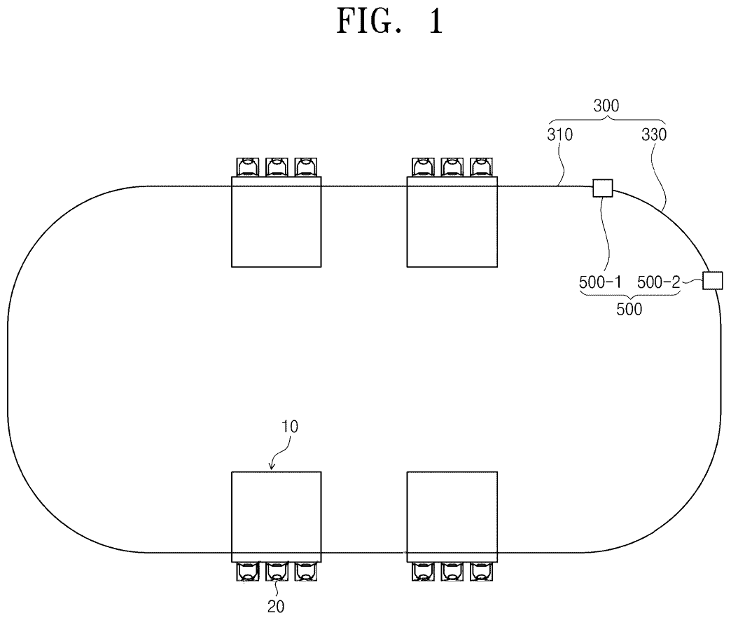

FIG. 1 is a plan view schematically showing an apparatus for transferring according to an embodiment of the present disclosure, viewed from above.

Referring to FIG. 1, an apparatus 1000 for transferring according to an embodiment of the present disclosure is capable of transporting containers 20, in which an article is stored, along a semiconductor manufacturing line in which semiconductor processing devices 10 are continuously arranged. The apparatus 1000 for transferring articles may include a rail 300, a transport vehicle 500, and a port P to be described below. The port P may be a load port provided in the semiconductor processing device 10, on which the container 20 is placed. Alternatively, the port P may be a port provided in a container storage device (not shown) storing the container 20. Alternatively, the port P may be a buffer frame installed on the ceiling of a semiconductor manufacturing line.

The rail 300 provides a path along which the transport vehicle 500 to be described below travels. The rail 300 may be fixedly installed on the ceiling of a semiconductor manufacturing line. In FIG. 1, the rail 300 is illustrated in a substantially hexagonal shape, but this is merely an embodiment and the shape of the rail 300 may be variously modified into a circular shape, a rectangular shape, etc. The rail 300 may be provided along the ceiling of a semiconductor manufacturing line and may be installed such that the semiconductor processing devices 10 can be identified from above. The installation range of the rail 300 may be arranged over a wide area so that the entire semiconductor processing devices 10 can be viewed. The rail 300 may include straight sections 310 and turning sections 330. In this configuration, the turning section 330 may be a curved section.

The transport vehicle may be an overhead hoist vehicle. The transport vehicle 500 can hold the container 20. The transport vehicle 500 can travel along a predetermined path on the rail 300. The transport vehicle 500 can travel along the rail 300 on the basis of a preset speed. A first speed that is the preset speed for the straight sections 310 may be faster than a second speed that is the preset speed for the curved sections. Further, a plurality of transport vehicles 500 may be provided, and a following transport vehicle 500-1 can sense the presence of a preceding transport vehicle 500-2, and can stop when there is a preceding transport vehicle.

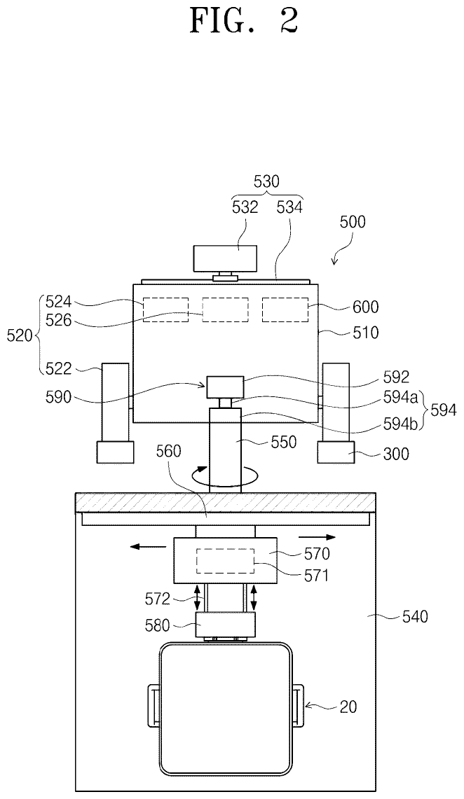

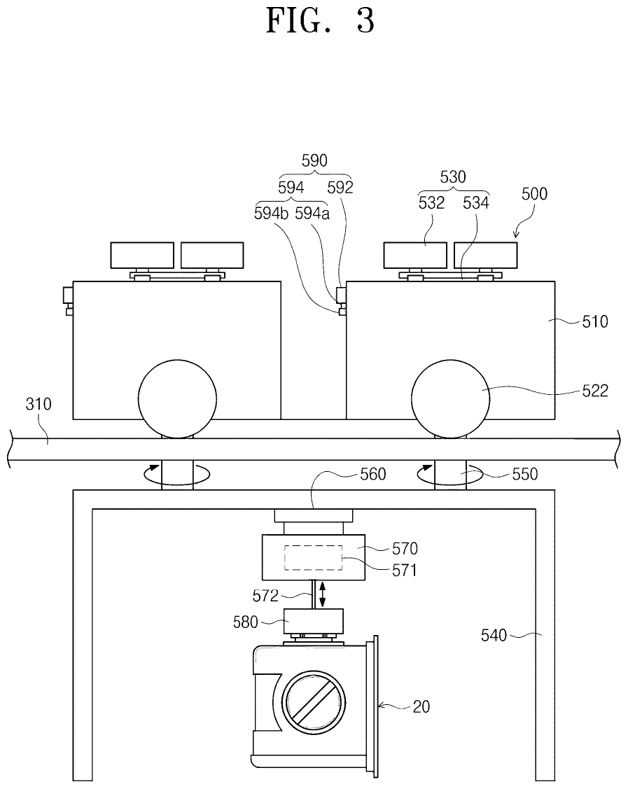

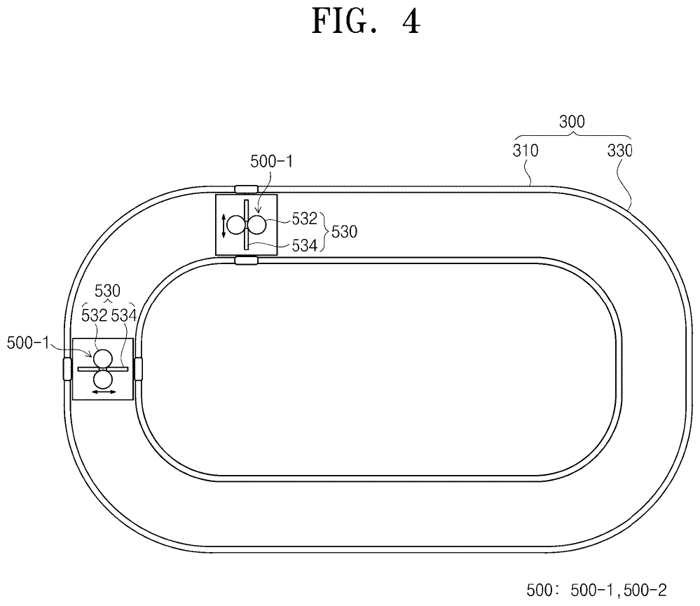

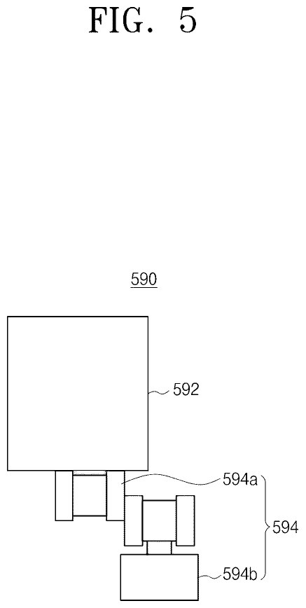

FIG. 2 is a plan view schematically showing a transport vehicle according to an embodiment of the present disclosure, viewed from the front, FIG. 3 is a plan view schematically showing the transport vehicle according to an embodiment of the present disclosure, viewed from the side, FIG. 4 is a plan view schematically showing a transport vehicle according to an embodiment of the present disclosure, viewed from above, and FIG. 5 is a conceptual view schematically showing a trolley sensor unit according to an embodiment of the present disclosure. Referring to FIG. 2 to FIG. 5, the transport vehicle 500 according to an embodiment of the present disclosure may include a body 510, a driving unit 520, a steering unit 530, a frame 540, a neck 550, a slider 560, a lifting unit 570, a grip unit 580, a trolley sensor unit 590, and a control unit 600.

The body 510 may be provided at the upper portion of the transport vehicle 500. A plurality of bodies 510 may be provided, but for the convenience of description, the transport vehicle 500 is described as including a single body 510.

The driving unit 520 may include a driving wheel 522, a driving-actuating unit 524, and an angle sensor 526.

The driving wheel 522 may be rotatably coupled to the body 510. The driving wheel 522 can be rotated in contact with the rail 300. A plurality of driving wheels 522 may be provided. The driving wheel 522 may be provided as a pair. Any one of the driving wheels 522 may be rotatably coupled to a first side of the body 510, and the other of the driving wheels 522 may be rotatably coupled to a second side opposite to the first side of the body 510. The driving wheel 522 can travel on the rail 300 by rotating in contact with the rail 300. The rail 522 can travel in the straight sections 310 and the turning sections 330.

When the driving wheel 522 travels in the straight sections 310, the angle of the driving wheel 522 can be maintained as constant. In this configuration, the angle of the driving wheel 522 may be a steering angle of the driving wheel 522. When the driving wheel 522 travels in the turning sections 330, the angle of the driving wheel 522 can be changed. That is, when the driving wheel 522 travels in the turning sections 330, the angle of the driving wheel 522 can be changed in real time on the basis of the location of the turning sections 330.

The driving-actuating unit 524 may be provided in the body 510. The driving-actuating unit 524 can rotate the driving wheel 522 by transmitting power to the driving wheel 522. The angle sensor 526 can sense the angle of the driving wheel 522. The angle sensor 526 can transmit a driving angle sensing value, which is a sensing value for the angle of the driving wheel 522, to the control unit 600.

The steering unit 530 may be provided over the body 510. The steering unit 530 may include a plurality of steering wheels 532 and a steering rail 534. The steering wheel 532 may be arranged in a direction parallel to the traveling direction of the transport vehicle 500 when viewed from above. Further, the longitudinal direction of the steering rail may be parallel to a direction perpendicular to the traveling direction of the transport vehicle 500 when viewed from above. Further, the position of the steering wheel 532 may be changed in the longitudinal direction of the steering rail 534.

The frame 540 may be provided at the lower portion of the transport vehicle 500. The frame 540 may have a cuboid shape with both sides and the bottom open. The frame 540 may have blocking plates at the front and rear. Accordingly, it is possible to prevent the container 20, which is held, from shaking due to air resistance, when the transport vehicle 500 travels.

The neck 550 may be coupled to the body 510. The neck 550 may be provided to be rotatable with respect to the body 510 and the frame 540. The frame 540 may be coupled to at least one or more bodies 510 through at least one or more necks 550. For example, the frame 540 may be provided as one, and two necks 550 can be coupled to one frame 540. Further, two necks 550 may be coupled to different bodies 510, respectively.

The slider 560 may be coupled to the frame 540. The slider 560 may be coupled such that its position can be changed with respect to the frame 540. The slider 560 may be provided in the internal space of the frame 540 and may be coupled to the bottom of the frame 540. The slider 560 may be coupled to the frame 540 such that its position can be changed to the left and right sides with respect to the traveling direction of the transport vehicle 500. Further, the slider 560 may be coupled to the lifting unit 570 to be described below. Accordingly, it is possible to change the position of the lifting unit 570 by changing the position of the slider 560.

The lifting unit 570 may be provided between the body 510 and the grip unit 580. The lifting unit 570 can move the grip unit 580 in the vertical direction. The lifting unit 570 can move up or down the grip unit 580. The lifting unit 570 may include a lifting actuator 571 and a belt 572. The lifting unit 570 may be referred to as a hoist device. The lifting actuator 571 can change the length of the suspended belt 572 by winding or unwinding the belt 572. For example, when the lifting actuator 571 unwinds the belt 572, the length of the belt 572 can be increased, and when the lifting actuator 571 winds the belt 572, the length of the belt 572 can be decreased. Further, a plurality of belts 572 may be provided. One end of each of the plurality of belts 572 may be connected to the grip unit 580.

The grip unit 580 can hold the container 20. When the grip unit 580 is closed, the grip unit 580 can hold the container 20. When the grip unit 580 is opened, the grip unit 580 can release the container 20. That is, the grip unit 580 can hold the container 20 in a detachable way. The grip unit 580 can unload the container 20 to and from the port P, such as a load port of a semiconductor processing device.

The trolley sensor unit 590 may be provided on the body 510. The trolley sensor unit 590 may be provided at the center on the front of the body 510. Although the trolley sensor unit 590 is described as being provided at a lower portion of the front of the body 510, this is merely an example and is not limited thereto.

The trolley sensor unit 590 may include a trolley sensor 592 and an actuating unit 594. The trolley sensor 592 can sense objects ahead of the transport vehicle 500. The trolley sensor 592 can sense other transport vehicles 500 ahead. The trolley sensor 592 can sense objects within a sensing angle among objects ahead. The sensing angle can be adjusted on the basis of the direction or angle that the trolley sensor 592 is facing. The trolley sensor 592 may include a proximity sensor, an infrared sensor, an ultrasonic sensor, an acceleration sensor, an angular acceleration sensor, a light sensor, etc., but is not limited thereto. The trolley sensor 592 can transmit a trolley sensing value, which is a sensing value of an object ahead, to the control unit 600.

The actuating unit 594 may be connected to trolley sensor 592. The actuating unit 594 can change the sensing angle of the trolley sensor 592. The actuating unit 594 may include a power transmission member 594a connected to the trolley sensor 592 and a power supply member 594b that supplies power to the power transmission member 594a. For example, the power transmission member 594a may be a gear member, a pulley member, or a toothed member, and the power supply member 594b may be a motor, but they are not limited thereto. The power supply member 594b can supply power to the power transmission member 594a, and the power transmission member 594a can be rotated by the supplied power, thereby being able to change the sensing angle of the trolley sensor 592.

The control unit 600 may be provided in the body 510. The control unit 600 can control at least one of the driving unit 520, slider 560, lifting unit 570, and trolley sensor unit 590.

The control unit 600 can receive a driving angle sensing value from the angle sensor 526 and a trolley sensing value from the trolley sensor 592. The control unit 600 can control at least one of the driving-actuating unit 524 and the actuating unit 594 on the basis of the driving angle sensing value and the trolley sensing value.

The control unit 600 can acquire a driving angle of the driving wheel 521 on the basis of a driving angle sensing value and can acquire a sensing angle of the trolley sensor 592 on the basis of a trolley sensing value.

The control unit 600 can command the actuating unit 594 to change the sensing angle of the trolley sensor 592 so that the driving angle and the sensing angle of the trolley sensor 592 are matched. When the transport vehicle 500 travels in the turning sections 330, the driving angle of the driving wheel 521 can be changed in real time. The control unit 600 can command the actuating unit 594 to change the sensing angle to match the driving angle that is changed in real time. In this way, by changing the sensing angle to match the driving angle, the possibility of collision between transport vehicles 500 can be reduced.

The control unit 600 can determine which sections, either the straight sections 310 or the turning sections 330, the transport vehicle 500 is traveling in, on the basis of the driving angle. The control unit 600 can determine whether the transport vehicle 500 has entered the turning sections 330.

For example, the control unit 600 can determine that the transport vehicle 500 is traveling in the straight sections 310 if the driving angle is within a preset range, and that the transport vehicle 500 is traveling in the turning sections 330 if the driving angle is outside the preset range. The control unit 600 can determine that the transport vehicle 500 has entered the turning sections 330 when the driving angle changes from within a preset range to outside the preset range. Further, the control unit 600 can determine that the transport vehicle 500 has entered the straight sections 310 when the driving angle changes from outside the preset range to within the preset range.

When the transport vehicle 500 enters the turning section 330, the control unit 600 can command the driving-actuating unit 524 to control the driving wheel 522 to decrease the driving speed of the transport vehicle 500. For example, the control unit 600 can command the driving-actuating unit 524 to control the driving wheel 522 to reduce the speed of the transport vehicle 500 from a first speed to a second speed.

Further, when the transport vehicle 500 enters the turning sections 330, the control unit 600 can determine whether there is another transport vehicle 500 preceding the transport vehicle 500 on the basis of the trolley sensing value. The control unit 600 can determine whether there is another transport vehicle 500 preceding the transport vehicle 500 on the basis of a preset number of times. When determining that there is another transport vehicle 500 within a preset number of times, the control unit 600 can command the driving-actuating unit 524 to control the driving wheel 522 to stop the transport vehicle 500. By repeatedly determining whether there is another transport vehicle 500 as described above, the control unit 600 can reduce the possibility of collision between transport vehicles 500.

When the transport vehicle 500 enters the straight sections 310, the control unit 600 can command the driving-actuating unit 524 to control the driving wheel 522 to increase the driving speed of the transport vehicle 500. For example, the control unit 600 can command the driving-actuating unit 524 to control the driving wheel 522 to increase the speed of the transport vehicle 500 from the second speed to the first speed.

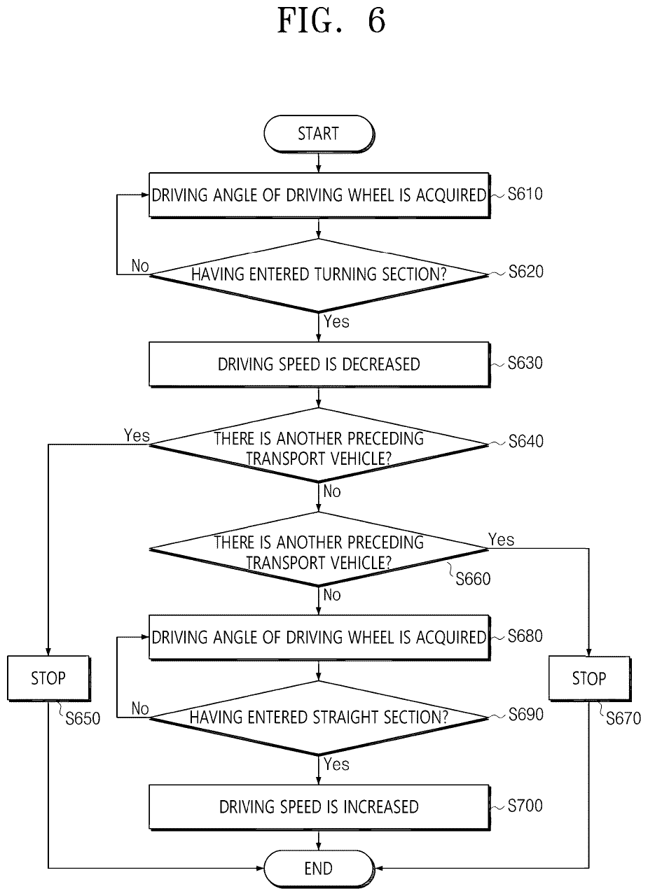

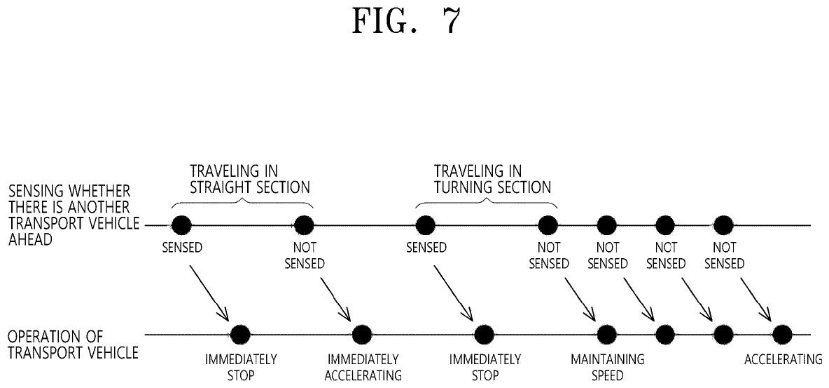

FIG. 6 is a flowchart showing a method of operating a transport vehicle according to an embodiment of the present disclosure. FIG. 7 is a conceptual view illustrating a transport method according to an embodiment of the present disclosure.

Referring to FIG. 6, a transport vehicle can acquire the driving angle of a driving wheel (S610). The transport vehicle 500 can sense the driving angle of the driving wheel 522 through the angle sensor 526.

The transport vehicle can determine whether it has entered a turning section (S620). The transport vehicle 500 can determine whether it has entered the turning section (330) on the basis of the sensed driving angle. When the driving angle is within a preset range, the transport vehicle 500 can determine that it has not entered the turning sections 330, and when the driving angle is outside the preset range, the transport vehicle 500 can determine that it has entered the turning sections 330.

When it is determined that the transport vehicle 500 has not entered the turning sections 330 (No in S620), it can be determined that the transport vehicle 500 is traveling in the straight sections 310, and the presence of another transport vehicle 500 ahead can be detected. Further, the transport vehicle 500 can return to S610 and acquire the driving angle of the driving wheel 522.

When it is determined that the transport vehicle 500 has entered the turning sections 330 (Yes in S620), the transport vehicle 500 can reduce its driving speed (S630). For example, the transport vehicle 500 can decrease the driving speed from the first speed to the second speed. Further, the transport vehicle 500 can change the sensing angle of the trolley sensor 592 to match the driving angle of the driving wheel 522.

The transport vehicle 500 can determine whether there is another transport vehicle 500 preceding the subject transport vehicle 500 (S640). The transport vehicle 500 can acquire a sensing value through the trolley sensor 592, and can determine whether there is another transport vehicle preceding the subject transport vehicle 500 on the basis of the acquired sensing value.

When it is determined that there is another transport vehicle preceding the subject transport vehicle 500 (Yes in S640), the transport vehicle 500 can stop (S650). The transport vehicle 500 can stop the driving wheel 522 through the driving-actuating unit 524.

When it is determined that there is no transport vehicle preceding the subject transport vehicle 500 (No in S640), the transport vehicle 500 can determine again whether there is another transport vehicle preceding the subject transport vehicle 500 (S660). The transport vehicle 500 can acquire again a sensing value through the trolley sensor 592, and can determine again whether there is another transport vehicle preceding the subject transport vehicle 500 on the basis of the re-acquired sensing value. In this case, the transport vehicle 500 can travel at a constant speed. Step S660 can be repeatedly performed.

When it is determined again that there is another transport vehicle preceding the subject transport vehicle 500 (Yes in S660), the transport vehicle 500 can stop (S670).

When there is no transport vehicle preceding the subject transport vehicle 500 (Yes in S660), the transport vehicle 500 can acquire the driving angle of the driving wheel 522 through the angle sensor 526 (S680).

The transport vehicle can determine whether it has entered a straight section (S690). When it is determined that the transport vehicle 500 has not entered the straight sections 310 (No in S690), the transport vehicle 500 can return to S680 and sense the driving angle of the driving wheel 522.

When it is determined that the transport vehicle 500 has entered the straight sections 310 (Yes in S690), the transport vehicle 500 can reduce its driving speed (S700). The transport vehicle 500 can increase the driving speed from the second speed to the first speed.

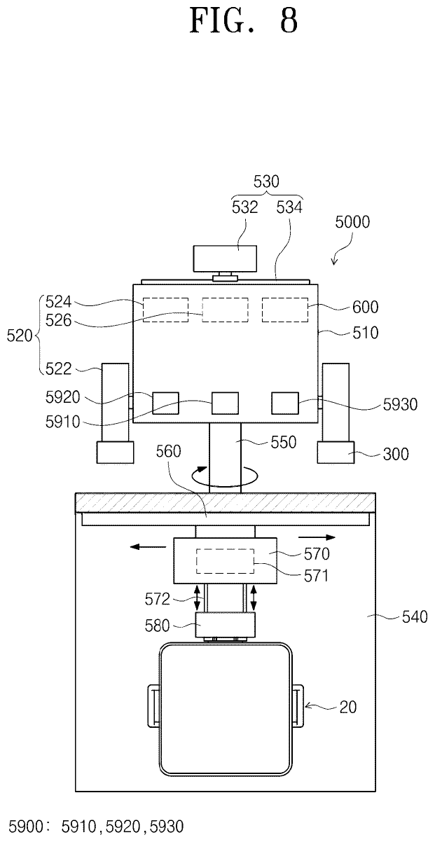

FIG. 8 is a plan view schematically showing a transport vehicle according to another embodiment of the present disclosure, viewed from the front.

Referring to FIG. 8 to FIG. 5, a transport vehicle 5000 according to another embodiment of the present disclosure may include a body 510, a driving unit 520, a steering unit 530, a frame 540, a neck 550, a slider 560, a lifting unit 570, a grip unit 580, a trolley sensor unit 5900, and a control unit 600.

The transport vehicle may include: a first trolley sensor 5910 provided at the center on the front of the body 510 and sensing objects ahead of the transport vehicle 5000; a second trolley sensor 5910 provided at one side of the front of the body 510 and sensing objects ahead of the transport vehicle 5000; and a third trolley sensor 5930 provided at the other side of the front of the body 510 and sensing objects ahead of the transport vehicle 5000. In this configuration, the first trolley sensor 5910, second trolley sensor 5920, and third trolley sensor 5930 may be the same as the trolley sensor 592 shown in FIG. 2. On the other hand, at least one of the first trolley sensor 5910, second trolley sensor 5920, and third trolley sensor 5930 may be the same as the trolley sensor unit 590 shown in FIG. 2. Sensing values of the first trolley sensor 5910, second trolley sensor 5920, and third trolley sensor 5930 can be transmitted to the control unit 600.

The control unit 600 can receive sensing values from the first trolley sensor 5910, second trolley sensor 5920, and third trolley sensor 5930. The control unit 600 can control the driving unit 520 and the trolley sensor unit 5900 on the basis of at least one of a driving angle sensing value, a sensing value of the first trolley sensor 5710, a sensing value of the second trolley sensor 5720, and a sensing value of the third trolley sensor 5730.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for transferring that comprises a transport vehicle transporting a container with an article therein, wherein the transport vehicle includes:
a driving unit including a driving wheel and an angle sensor sensing a driving angle sensing value;
a trolley sensor unit including a first trolley sensor provided at a center on a front of the transport vehicle and sensing objects ahead of the transport vehicle; and
a control unit controlling at least one of the driving unit and the trolley sensor unit on the basis of a driving angle sensing value of the angle sensor and a first trolley sensing value of the first trolley sensor.

2. The apparatus of claim 1, wherein the trolley sensor unit includes an actuating unit changing a sensing angle of the first trolley sensor.

3. The apparatus of claim 2, wherein the actuating unit includes:
a power transmission member connected to the first trolley sensor; and
a power supply member supplying power to the power transmission member.

4. The apparatus of claim 2, wherein the control unit controls the actuating unit on the basis of the driving angle sensing value such that the driving angle and the sensing angle are matched.

5. The apparatus of claim 1, wherein the control unit
determines whether the transport vehicle has entered a turning section on the basis of the driving angle sensing value when the transport vehicle is traveling in a straight section at a first speed;
controls the driving unit to decrease a driving speed of the transport vehicle from the first speed to a second speed when the transport vehicle has entered the turning section; and
determines whether there is another transport vehicle preceding the transport vehicle on the basis of the first trolley sensing value.

6. The apparatus of claim 5, wherein when there is the other transport vehicle, the control unit controls the driving unit to stop the transport vehicle.

7. The apparatus of claim 5, wherein the control unit repeatedly determines whether there is the other transport vehicle on the basis of the first trolley sensing value.

8. The apparatus of claim 7, wherein the control unit determines whether the transport vehicle has entered the straight section on the basis of the driving angle sensing value when there is no other transport vehicle as the result of determination; and
controls the driving unit to increase the driving speed of the transport vehicle from the second speed to the first speed when the transport vehicle has entered the straight section.

9. The apparatus of claim 1, wherein the trolley sensor unit further includes:
a second trolley sensor provided at one side of the front of the transport vehicle and sensing objects ahead of the transport vehicle; and
a third trolley sensor provided at another side of the front of the transport vehicle and sensing objects ahead of the transport vehicle.

10. The apparatus of claim 9, wherein the control unit controls the driving unit and the trolley sensor unit on the basis of at least one of the driving angle sensing value, the first trolley sensing value, a second trolley sensing value of the second trolley sensor, and a third sensing value of the third trolley sensor.

11. The apparatus of claim 1, further comprising:
a rail installed on a ceiling of a manufacturing line where semiconductor processing devices are continuously arranged; and
a port configured such that the container can be seated thereon.

12.-16. (Cancelled)

17. An apparatus for transferring, comprising:
a rail provided along a ceiling;
a port configured such that a container can be seated thereon; and
a transport vehicle traveling along the rail and transporting the container to the port,
wherein the transport vehicle includes:
a driving unit having a driving wheel;
an angle sensor unit including an angle sensor sensing a driving angle sensing value;
a trolley sensor unit including a first trolley sensor provided at a center on a front of the transport vehicle and sensing objects ahead of the transport vehicle; and
a control unit controlling at least one of the driving unit and the trolley sensor unit on the basis of a driving angle sensing value of the angle sensor and a first trolley sensing value of the first trolley sensor,
wherein the trolley sensor unit includes an actuating unit changing a sensing angle of the first trolley sensor,
wherein the actuating unit includes:
a power transmission member connected to the first trolley sensor; and
a power supply member supplying power to the power transmission member,
wherein the control unit
controls the actuating unit on the basis of the driving angle sensing value such that the driving angle and the sensing angle are matched;
determines whether the transport vehicle has entered a turning section on the basis of the driving angle sensing value when the transport vehicle is traveling in a straight section at a first speed;
controls the driving unit to decrease a driving speed of the transport vehicle from the first speed to a second speed when the transport vehicle has entered the turning section; and
determines whether there is another transport vehicle preceding the transport vehicle on the basis of the first trolley sensing value.

18. The apparatus of claim 17, wherein when there is the other transport vehicle, the control unit controls the driving unit to stop the transport vehicle.

19. The apparatus of claim 17, wherein the control unit
repeatedly determines whether there is the other transport vehicle on the basis of the first trolley sensing value;
determines whether the transport vehicle has entered the straight section on the basis of the driving angle sensing value when there is no other transport vehicle as the result of determination; and
controls the driving unit to increase the driving speed of the transport vehicle from the second speed to the first speed when the transport vehicle has entered the straight section.

20. The apparatus of claim 17, wherein the trolley sensor unit further includes:
a second trolley sensor provided at one side of the front of the transport vehicle and sensing objects ahead of the transport vehicle; and
a third trolley sensor provided at another side of the front of the transport vehicle and sensing objects ahead of the transport vehicle, and
the control unit controls the driving unit and the trolley sensor unit on the basis of at least one of the driving angle sensing value, the first trolley sensing value, a second trolley sensing value of the second trolley sensor, and a third sensing value of the third trolley sensor.
